(19) United States
(12) Patent Application Publication
(10) Pub. No.: US 2026/0215032 A1
(43) Pub. Date: Jul. 23, 2026

(54) METHOD FOR MANUFACTURING ULTRAVIOLET LIGHT-EMITTING DEVICE

(71) Applicant: WAVELORD CO., LTD, Hwaseong-si (KR)

(72) Inventors: Juneo SONG, Suwon-si (KR); Ji Hyung MOON, Gunpo-si (KR)

(73) Assignee: WAVELORD CO., LTD, Hwaseong-si (KR)

(21) Appl. No.: 19/145,937

(22) PCT Filed: Jan. 19, 2024
(86) PCT No.: PCT/KR2024/000961

§ 371 Date: Jul. 5, 2025

(30) Foreign Application Priority Data
Jan. 19, 2023 (KR) 10-2023-0007759

(51) Int. Cl. H10H 20/01

(52) U.S. Cl. CPC H10H 20/016; H10H 20/0133

(57) ABSTRACT

The present invention relates to a method for manufacturing an ultraviolet light-emitting device and, more specifically, to a method for manufacturing an ultraviolet light-emitting device that is capable of high current application, can emit high-power deep ultraviolet rays, and has a thin film-type chip structure with significantly improved heat dissipation ability.

### TECHNICAL FIELD

The present invention relates to a method of manufacturing an ultraviolet light-emitting device, and more particularly, to a method of manufacturing an ultraviolet light-emitting device having a thin-film chip structure that allows high current to be applied and enables emission of high-power deep ultraviolet rays.

### BACKGROUND ART

Deep ultraviolet light-emitting diodes (LEDs) having a wavelength band of 362 nm or less are widely used depending on the specific wavelength band, not only for industrial curing and exposure processes but also in medical devices for skin and dental treatment, surgical instruments, sterilization of various microorganisms and viruses, and water treatment. Since most of these applications involve direct irradiation, the development of thin-film chip structures with high power performance has been in high demand in the industry.

Specifically, although it is required to achieve a high optical power of 100 mW or more by applying a high current of 350 mA or more during operation, and at the same time, secure stable reliability and a lifespan of 1,000 hours or more by applying high heat dissipation technology, the main products currently under development and mass production have an optical power performance of less than 100 mW, which is low-power or middle-power, by applying a current of less than 350 mA and have a flip chip structure equipped with a thick-film sapphire with a thickness of 200 μm or more, and deep ultraviolet LEDs with a thin-film chip structure do not exist.

Against this background, there is a growing need for the development of deep ultraviolet LEDs having a thin-film chip structure with a high power of 100 mW or more, but the following issues exist.

First, when an epitaxial structure composed of Al-rich AlGaN is grown on a sapphire growth substrate, a high density of crystal defects is present in the epitaxial structure. Furthermore, in order to design and fabricate thin chips, the sapphire, which is an initial growth substrate, must be separated and removed. For this purpose, a sacrificial separation layer that absorbs a 248 nm laser beam must be introduced below a deep ultraviolet active layer (multi-quantum wells, MQWs), but growing a high-quality deep ultraviolet active layer on such a sacrificial separation layer requires significant technical expertise.

Next, when a high-Al-composition AlₓGa₁₋ₓN (x>0.4) layer or the like is introduced to minimize optical absorption, since current injection in a vertical direction and current spreading in a horizontal direction become inefficient, there is a problem that current and heat are concentrated in a local region. In particular, in high-power thin-film chips, current crowding becomes more severe as the applied current increases, making it difficult to apply a high current of 350 mA or more. Accordingly, recent designs have attempted to increase the number of via holes in a light-emitting region, but performance remains at a similar level regardless of an increase or decrease in the number of via holes.

Furthermore, when designing thin-film chips at the wafer level, residual stress within the chip may lead to structural and thermal instability, and in cases in which significant heat is generated due to optical absorption, there is no effective means of dissipating the heat.

### DISCLOSURE

### Technical Problem

The present invention is directed to solving the above-mentioned conventional problems and providing a method of manufacturing an ultraviolet light-emitting device having a thin-film chip structure that allows high current to be applied and enables emission of high-power deep ultraviolet rays.

### Technical Solution

According to the present invention, the above objective is achieved by a method of manufacturing an ultraviolet light-emitting device, including a first formation operation of forming a nucleation layer on a growth substrate, a second formation operation of forming a sacrificial separation layer on the nucleation layer, a growth operation of growing a light-emitting layer on the sacrificial separation layer, a bonding operation of bonding the light-emitting layer to a support substrate, a first removal operation of removing the growth substrate, the nucleation layer, and the sacrificial separation layer, and a fabrication (FAB) operation of forming a light-emitting device structure by performing a FAB process on the light-emitting layer.

Further, the nucleation layer may include a low-temperature growth layer and a high-temperature growth layer, which is formed on the low-temperature growth layer and grown at a higher temperature than the low-temperature growth layer, and a plurality of air voids may be formed within the high-temperature growth layer.

Further, the sacrificial separation layer may be formed as a multilayer thin film with a superlattice structure.

Further, the sacrificial separation layer may include at least one superlattice unit layer, wherein the superlattice unit layer may include at least one of an AlN layer, an AlₓGa₁₋ₓN layer, or an Al_{y}Ga_{1-y}N layer, wherein, in a case where y>x, the AlₓGa₁₋ₓN layer may satisfy x≤0.48, and in a case where x>y, the Al_{y}Ga_{1-y}N layer may satisfy y≤0.48.

Further, the light-emitting layer may include an n-type semiconductor layer, an active layer, an electron blocking layer, and a p-type semiconductor layer.

Further, a seed layer and a polycrystalline diamond (PCD) layer may be sequentially stacked on the support substrate, and in the bonding operation, the light-emitting layer may be bonded to the PCD layer.

Further, the method may further include a second removal operation of removing the support substrate and the seed layer after the FAB operation.

Further, in the FAB operation, the FAB process may be performed such that a width of each of divided portions of the light-emitting layer is formed to be less than or equal to a current spreading length.

Further, in the FAB operation, the FAB process may be performed such that an n-type ohmic contact electrode surrounds a periphery of each of the divided portions of the light-emitting layer.

### Advantageous Effects

According to the present invention, it is possible to manufacture an ultraviolet light-emitting device having a thin-film chip structure that allows a high current of 350 mA or more to be applied, enables emission of deep ultraviolet light with a high power of 100 mW or more, and exhibits significantly improved heat dissipation capability.

Meanwhile, the effects of the present invention are not limited to the above-mentioned effects, and various effects may be included within the scope which is apparent to those skilled in the art from contents to be described below.

### DESCRIPTION OF DRAWINGS

FIG. 1 is a flowchart illustrating a method of manufacturing an ultraviolet light-emitting device according to a first embodiment of the present invention.

FIG. 2 illustrates a process of manufacturing an ultraviolet light-emitting device according to the method of manufacturing an ultraviolet light-emitting device according to the first embodiment of the present invention.

FIG. 3 is a flowchart illustrating a method of manufacturing an ultraviolet light-emitting device according to a second embodiment of the present invention.

FIG. 4 illustrates a process of manufacturing an ultraviolet light-emitting device according to the method of manufacturing an ultraviolet light-emitting device according to the second embodiment of the present invention.

FIG. 5 is a plan view of a conventional ultraviolet light-emitting device.

FIG. 6 is a cross-sectional view taken along line A-A′ of FIG. 5.

FIGS. 7 and 8 are plan views of ultraviolet light-emitting devices manufactured according to the method of manufacturing an ultraviolet light-emitting device according to the first or second embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number as much as possible, even though the same components are shown in different drawings.

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define the nature, order, or sequence of a corresponding component but used merely to distinguish the corresponding component from other component(s).

Hereinafter, a method (S100) of manufacturing an ultraviolet light-emitting device according to a first embodiment of the present invention will be described in detail with reference to the accompanying drawings.

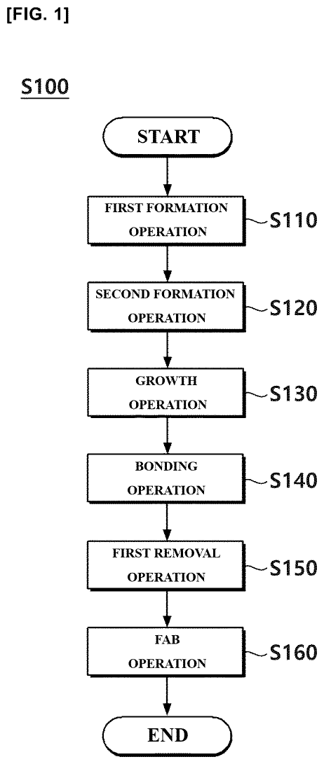

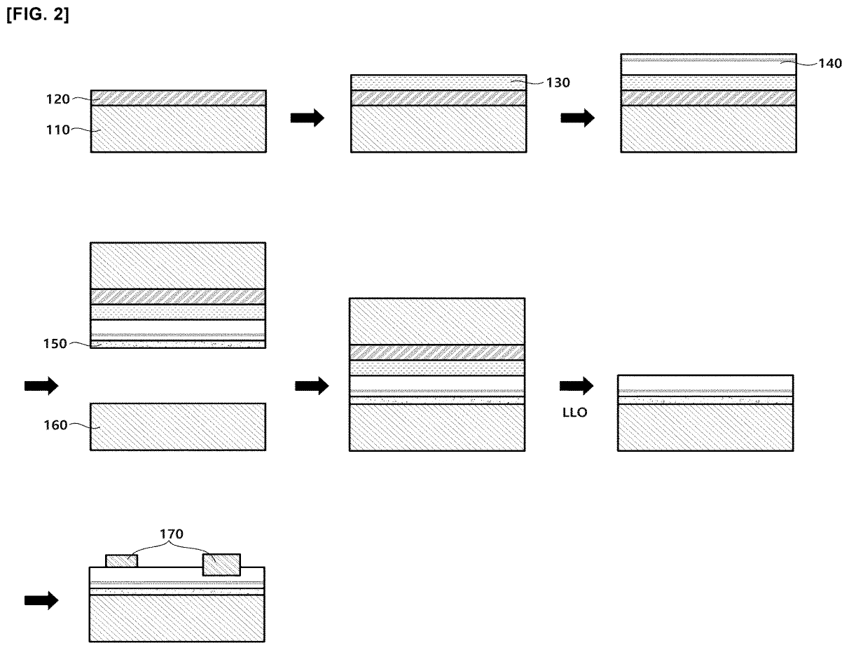

FIG. 1 is a flowchart illustrating the method (S100) of manufacturing an ultraviolet light-emitting device according to the first embodiment of the present invention, and FIG. 2 illustrates a process of manufacturing an ultraviolet light-emitting device according to the method (S100) of manufacturing an ultraviolet light-emitting device according to the first embodiment of the present invention.

As shown in FIGS. 1 and 2, the method (S100) of manufacturing an ultraviolet light-emitting device according to the first embodiment of the present invention includes a first formation operation S110, a second formation operation S120, a growth operation S130, a bonding operation S140, a first removal operation S150, and a fabrication (FAB) operation S160.

The first formation operation S110 is an operation of forming a nucleation layer 120 on a growth substrate 110.

The growth substrate 110 is removed in the first removal operation S150, which will be described below, using a laser lift-off (LLO) technique, and in this case, it is preferable that the growth substrate 110 is provided as an optically transparent and high-temperature-resistant substrate that theoretically allows 100% transmittance of a 248 nm laser beam without absorption. For example, the growth substrate 110 may be formed of sapphire (α-phase Al₂O₃) that is mirror-polished on both surfaces. Although the growth substrate 110 may also be formed of other materials such as ScMgAlO₄, 4H—SiC, or 6H—SiC, the following description will be provided based on a sapphire growth substrate 110.

Further, the growth substrate 110 is preferably provided as a patterned sapphire substrate (PSS) having protrusions patterned in various dimensions (sizes and shapes) at microscale or nanoscale, either regularly or irregularly, in order to minimize crystal defects in a light-emitting layer 140 grown thereon.

The nucleation layer 120 is an essential region for improving the quality of the deep ultraviolet light-emitting layer 140, which is formed as an epitaxial thin film composed of Al-rich AlGaN. The nucleation layer 120 includes a low-temperature growth layer and a high-temperature growth layer.

The low-temperature growth layer is a single or multilayer low-temperature aluminum nitride (LT-AlN) layer formed at a temperature of 900° C. or lower, and performs a nucleation function for the growth of the high-temperature growth layer formed thereon.

The high-temperature growth layer, which is a layer grown on the low-temperature growth layer to improve the quality of a sacrificial separation layer 130 to be formed on the high-temperature growth layer, refers to a single or multilayer high-temperature aluminum nitride (HT-AlN) grown at a temperature of 1000° C. or higher, which is higher than the temperature used for the low-temperature growth layer, and is preferably formed to have a thickness of approximately 3 μm.

As the wavelength of ultraviolet light decreases, the Al content in the light-emitting layer 140 increases. Accordingly, although it is ideal to use an AlN substrate as the growth substrate 110 in terms of thermal expansion coefficient and lattice constant, since the AlN substrate is excessively expensive and lacks light transmittance, there is a disadvantage in that it cannot be separated using an LLO technique. Accordingly, in the present invention, a thick AlN layer is formed on the sapphire growth substrate 110 having excellent light transmittance and is used as an AlN template, and the sacrificial separation layer 130 is disposed on the AlN layer to absorb a laser beam, thereby enabling the removal of the growth substrate 110 through an LLO technique and realizing a thin-film chip structure.

At this time, due to strong tensile stress within the high-temperature growth layer, multiple cracks may occur in the thin film of the light-emitting layer 140, and to prevent this, in the present invention, a plurality of air voids may be formed inside the high-temperature growth layer to compensate for the tensile stress.

The second formation operation S120 is an operation of forming the sacrificial separation layer 130 on the high-temperature growth layer of the nucleation layer 120.

The sacrificial separation layer 130 is formed as a multilayer thin film having a superlattice (SL) structure so that the deep ultraviolet light-emitting layer 140 can be grown thereon with high quality without defects, and at the same time, the sacrificial separation layer 130 is formed of a material capable of easily absorbing a 248 nm laser beam, thereby enabling the growth substrate 110 to be easily removed through an LLO technique in the first removal operation S150, which will be described below.

Specifically, the sacrificial separation layer 130 for this purpose includes at least one superlattice unit layer, which may include at least one of an AlN layer, an AlₓGa₁₋ₓN layer, or an Al_{y}Ga_{1-y}N layer, and preferably, an AlN layer/AlₓGa₁₋ₓN layer/Al_{y}Ga_{1-y}N layer may constitute one unit layer.

At this time, in order to absorb a 248 nm laser beam, the Al composition must be 48% or less. Accordingly, when y>x, the AlₓGa₁₋ₓN layer may satisfy x≤0.48, and when x>y, the Al_{y}Ga_{1-y}N layer may satisfy y≤0.48.

The growth operation S130 is an operation of epitaxially growing the high-quality deep ultraviolet light-emitting layer 140 on the sacrificial separation layer 130 having a superlattice structure.

The light-emitting layer 140 may include an n-type semiconductor layer (e.g., an n-type AlGaN layer), an active layer (multiple quantum wells (MQWs), e.g., AlₐGa₁₋ₐN layer/Al_{b}Ga_{1-b}N or AlGaN layer/AlN layer) configured to generate light through recombination of electrons and holes, an electron blocking layer (EBL) (e.g., a p-type AlGaN layer), and a p-type semiconductor layer (e.g., a p-type (Al)GaN layer).

The bonding operation S140 is an operation of bonding the light-emitting layer 140 to a support substrate 160 through a bonding layer 150.

Here, the support substrate 160 may be formed of a single-crystal material such as Si, SiC, or diamond having high heat-dissipation capability, or of a cost-effective polycrystalline ceramic material such as AlNcera, SiNcera, or SiCcera, but is not limited thereto and may be freely selected according to the application and requirements.

In addition, the bonding layer 150 may be formed of n-type ohmic contact electrodes 171 functioning as common electrodes.

The first removal operation S150 is an operation of exposing the light-emitting layer 140 by removing the growth substrate 110, the nucleation layer 120, and the sacrificial separation layer 130 using an LLO technique.

More specifically, in the first removal operation S150, a 248 nm laser beam may be irradiated onto a rear surface of the sapphire growth substrate 110 so that the sacrificial separation layer 130 absorbs the laser light, thereby separating the growth substrate 110 and the nucleation layer 120 from the light-emitting layer 140 by utilizing the phenomenon in which the sacrificial separation layer 130 melts through material decomposition caused by a chemical reaction at high temperature, and the sacrificial separation layer 130 remaining after separation may be removed through wet etching or the like to expose one surface of the light-emitting layer 140.

The FAB operation S160 is an operation of forming a light-emitting device structure by performing a FAB process on the exposed light-emitting layer 140.

Specifically, in the FAB operation S160, depending on the required structure, via holes may be formed in a portion of the light-emitting layer 140, or partial MESA etching may be performed. Subsequently, an ohmic contact electrode 170 and a passivation layer P are each formed to form a deep ultraviolet light-emitting device structure on the high heat-dissipation support substrate 160.

Meanwhile, when structurally necessary, the FAB operation S160 may also be partially performed after the growth operation S130. That is, in the present invention, the FAB operation S160 may be performed after the growth operation S130 and/or the first removal operation S150.

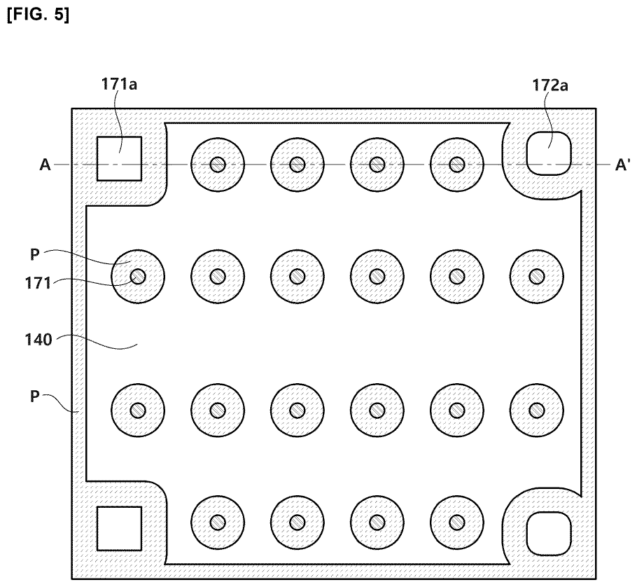

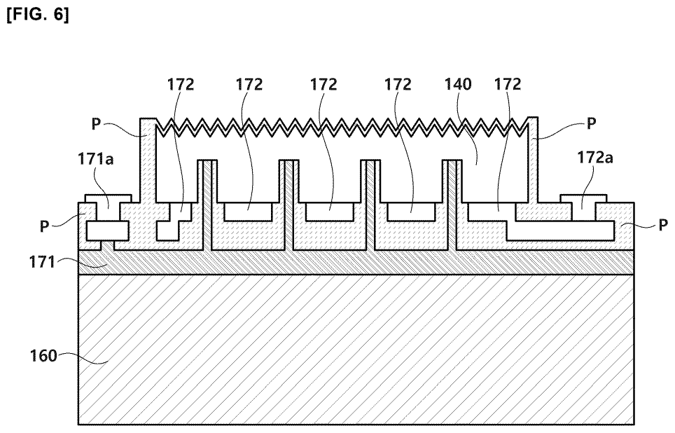

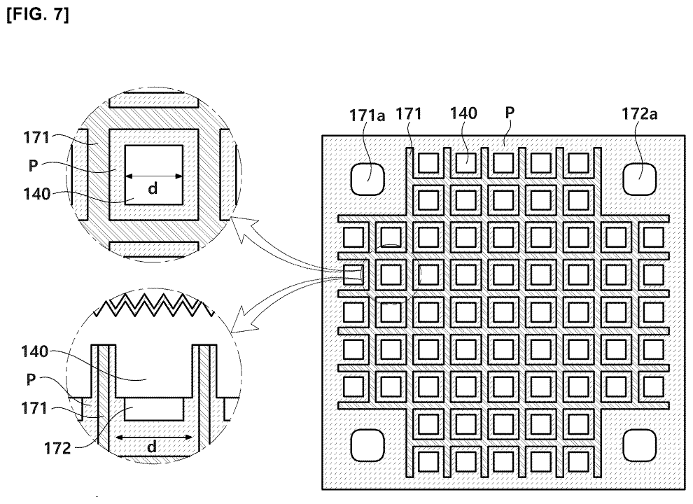

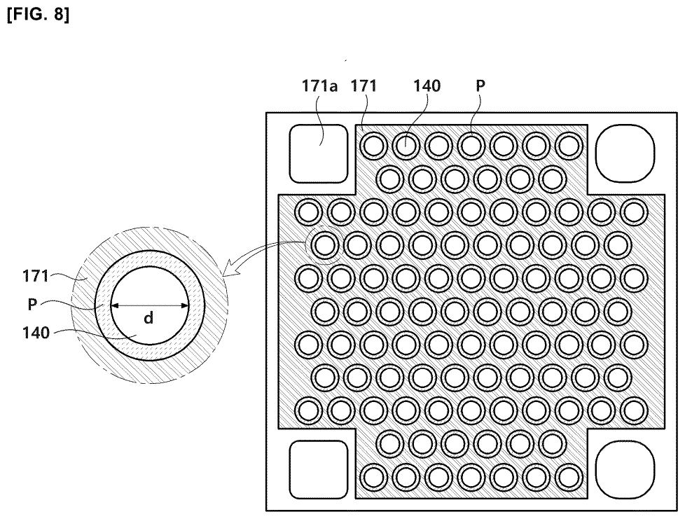

FIG. 5 is a plan view of a conventional ultraviolet light-emitting device, FIG. 6 is a cross-sectional view taken along line A-A′ of FIG. 5, and FIGS. 7 and 8 are plan views of ultraviolet light-emitting devices manufactured according to the method of manufacturing an ultraviolet light-emitting device according to the first or second embodiment of the present invention.

For example, in a case in which the FAB operation S160 is performed after the growth operation S130, the light-emitting layer 140 is grown in the growth operation S130, and then a plurality of via holes communicating with the n-type semiconductor layer are formed in the light-emitting layer 140. P-type ohmic contact electrodes 172 are formed in regions in which the via holes are not formed, and then the passivation layer P is formed to cover both the via holes and the p-type ohmic contact electrodes 172.

Thereafter, the passivation layer P on the via holes is etched to form electrical pathways to the n-type semiconductor layer, and then the n-type ohmic contact electrodes 171 are formed to fill the electrical pathways, such that the n-type ohmic contact electrodes 171 are connected in a parallel structure through a single layer. That is, the n-type ohmic contact electrodes 171 are formed to have the structure of common electrodes while also functioning as the bonding layer 150.

Thereafter, in the bonding operation S140, the n-type ohmic contact electrode 171 is bonded to the high heat-dissipation support substrate 160, and in the first removal operation S150, the growth substrate 110 is removed. Then, in the subsequent FAB operation S160, an n-type pad 171a electrically connected to the n-type ohmic contact electrode 171 and a p-type pad 172a electrically connected to the p-type ohmic contact electrode 172 are formed. Thereafter, processes such as surface texturing and formation of the passivation layer P are performed to manufacture an ultraviolet light-emitting device having the structure shown in FIGS. 5 and 6.

However, AlGaN-based deep ultraviolet light-emitting devices employ a high Al composition to reduce light absorption, which causes a problem of a decrease in electrical conductivity. That is, the ultraviolet light-emitting devices having a via-hole structure as shown in FIGS. 5 and 6 have a relatively large light-emitting region, which leads to poor lateral current spreading. As a result, current and heat become locally concentrated, causing non-uniform light emission and reduced reliability.

Accordingly, as shown in FIGS. 7 and 8, in the present invention, in the FAB operation S160 performed after the growth operation S130 and/or the first removal operation S150, the light-emitting layer 140 may be divided by MESA etching in consideration of current spreading, thereby forming a pixel structure (e.g., a grid-dense structure or a circular-dense structure), and a width d of each of the divided portions of the light-emitting layer 140 may be formed to be less than or equal to a current spreading length. For example, when a current spreading distance is 100 μm at a driving current of 350 mA, the width d of each divided portion of the light-emitting layer 140 may be set to within 100 μm to separate the light-emitting regions.

Further, in the FAB operation S160, the FAB process may be performed such that the n-type ohmic contact electrode 171 surrounds the perimeter of each divided portion of the pixel-structured light-emitting layer 140, thereby providing the advantage of achieving highly uniform light emission. Furthermore, as shown in FIG. 8, when the divided portions of the light-emitting layer 140 are arranged in a dense circular structure, there is an advantage in terms of light extraction compared to a grid-dense structure.

According to the structures described above, there is an effect that regions that are composed of high-resistance Al-rich AlGaN epitaxial layers in the conventional structures, have difficulty in spreading current and thus do not contribute to light emission, and deteriorate due to high temperatures generated during the operation of the light-emitting device to cause reliability degradation can be removed in advance.

Hereinafter, a method (S200) of manufacturing an ultraviolet light-emitting device according to a second embodiment of the present invention will be described in detail with reference to the accompanying drawings.

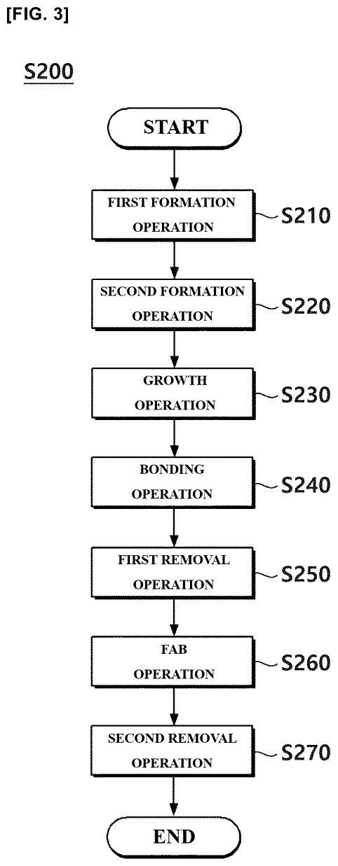

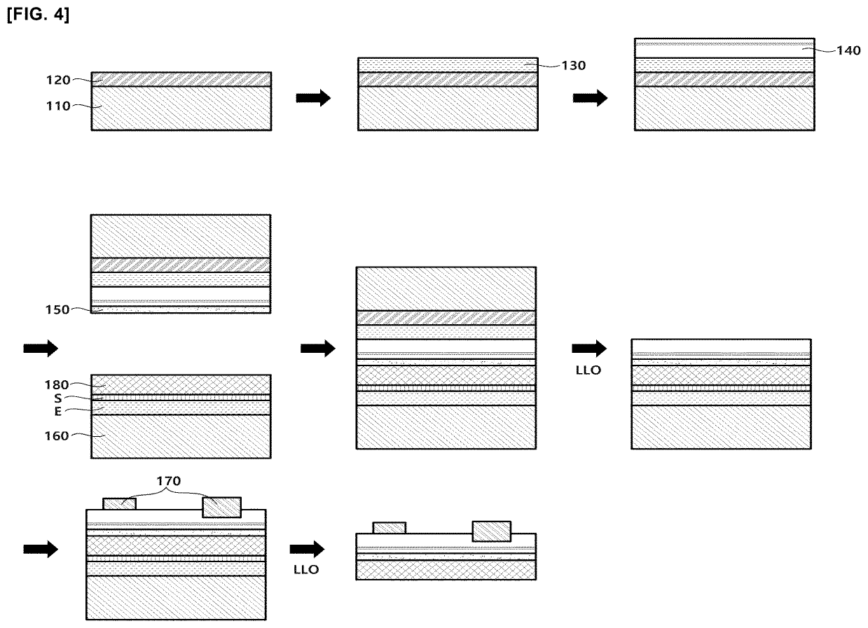

FIG. 3 is a flowchart illustrating the method (S200) of manufacturing an ultraviolet light-emitting device according to the second embodiment of the present invention, FIG. 4 is a view illustrating a process of manufacturing an ultraviolet light-emitting device according to the method (S200) of manufacturing an ultraviolet light-emitting device according to the second embodiment of the present invention, FIG. 5 is a plan view of a conventional ultraviolet light-emitting device, FIG. 6 is a cross-sectional view taken along line A-A′ of FIG. 5, and FIGS. 7 and 8 are plan views of ultraviolet light-emitting devices manufactured according to the method of manufacturing an ultraviolet light-emitting device according to the first or second embodiment of the present invention.

As shown in FIGS. 3 and 4, the method (S200) of manufacturing an ultraviolet light-emitting device according to the second embodiment of the present invention includes a first formation operation S210, a second formation operation S220, a growth operation S230, a bonding operation S240, a first removal operation S250, a FAB operation S260, and a second removal operation S270.

Here, since the first formation operation S210, the second formation operation S220, and the growth operation S230 are the same as those in the method (S100) of manufacturing an ultraviolet light-emitting device according to the first embodiment of the present invention, redundant descriptions thereof will be omitted.

Meanwhile, as described in the method (S100) of manufacturing an ultraviolet light-emitting device according to the first embodiment of the present invention, the FAB operation S260 may be partially performed even after the growth operation S230, when structurally necessary.

In the bonding operation S240, a light-emitting layer 140 is bonded to a polycrystalline diamond (PCD) layer 180 of a support substrate 160.

In the method (S200) of manufacturing an ultraviolet light-emitting device according to the second embodiment of the present invention, a sacrificial layer E, a seed layer S, and the PCD layer 180 may be sequentially stacked on the support substrate 160.

In the present embodiment, the support substrate 160 serves as a temporary substrate that is removed by an LLO technique in the second removal operation S270, which will be described below, and is preferably provided as an optically transparent and high-temperature-resistant substrate, which, like the growth substrate 110, theoretically allows 100% transmittance of a 248 nm laser beam without absorption. For example, the support substrate 160 may be formed of sapphire (α-phase Al₂O₃) that is mirror-polished on both surfaces. Although the support substrate 160 may also be formed of other materials such as ScMgAlO₄, 4H—SiC, or 6H—SiC, the following description will be provided based on a sapphire support substrate 160.

The sacrificial layer E is a layer that is sacrificed and separated by a laser beam in an LLO technique to facilitate the detachment of the support substrate 160, and may be formed of a material such as GaN or InGaN on the support substrate 160.

The seed layer S serves as a seed for forming the PCD layer 180, which will be described below, and is formed on the sacrificial layer E. The seed layer S may be formed of SiNx, AlN, or the like, but the present invention is not limited thereto.

The PCD layer 180 is formed as a thin film on the seed layer S and is formed of polycrystalline diamond. The PCD layer 180 supports the ultraviolet light-emitting device structure thereon after the support substrate 160 is removed in the second removal operation S270, which will be described below, and provides high heat-dissipation capability while enabling a thin ultraviolet light-emitting device. The PCD layer 180 may have a thickness of 10 μm to 300 μm.

Meanwhile, conventionally, warping of an epitaxy wafer may occur due to thermo-mechanical induced stress induced by differences in lattice constant (LC) and coefficient of thermal expansion (CTE) between the growth substrate 110 and the light-emitting layer 140. However, in the present invention, this issue can be resolved by firmly bonding the support substrate 160, which has almost no difference in CTE from the growth substrate 110, to one surface of the light-emitting layer 140 via a bonding layer 150. That is, in the case of the epitaxy wafer in which the support substrate 160 having the same or similar CTE as the growth substrate 110 is bonded, the epitaxy wafer may be in a stress-relieved state, thereby minimizing wafer bow to nearly zero. Accordingly, there is an advantage in that it can be applied to wafer sizes of 4 inches, 6 inches, 8 inches, and even 12 inches or larger.

The first removal operation S250 and the FAB operation S260 are the same as those of the method (S100) of manufacturing an ultraviolet light-emitting device according to the first embodiment of the present invention, and thus redundant descriptions thereof will be omitted.

The second removal operation S270 is an operation of removing the support substrate 160 and the seed layer S by using an LLO technique after the FAB operation S260.

More specifically, in the second removal operation S270, a 248 nm laser beam may be irradiated onto a rear surface of the sapphire support substrate 160 so that the sacrificial layer E absorbs the laser light, thereby separating the support substrate 160 from the seed layer S by utilizing the phenomenon in which the sacrificial layer E melts through material decomposition caused by a chemical reaction at high temperature, and the sacrificial layer E and the seed layer S remaining after separation may be removed through wet etching or the like, thereby manufacturing a deep ultraviolet light emitting device having the thin PCD layer 180 with high heat-dissipation capability.

Although all the components constituting the embodiments of the present invention have been described as being combined or combined to operate as one, the present invention is not essentially limited to the embodiments. That is, one or more of all the components may be selectively combined to operate as one within the scope of the present invention.

Further, since the terms, such as “comprising,” “including,” or “having” may mean that the corresponding component may be included unless specifically stated otherwise, it should be construed that another component is not excluded but may be further included. Unless defined otherwise, all terms used herein, including technical or scientific terms, have the same meanings as those generally understood by those skilled in the art to which the present invention pertains. Commonly used terms, such as terms defined in dictionaries, should be interpreted according to their context meanings in the related art, and are not to be interpreted with ideal or excessively formal meanings unless explicitly defined in the present invention.

In addition, the above description is a simple exemplary description of the technical spirit of the present invention, and the present invention may be variously modified and altered by those skilled in the art to which the present invention pertains without departing from the essential features of the present invention.

Accordingly, the embodiments disclosed in the present invention are not provided to limit the technical spirit of the embodiments of the present invention but provided to describe the present invention, and the scope of the technical spirit of the present invention is not limited by the embodiments. The scope of protection of the present invention should be construed by the attached claims, and all technical ideas within the equivalent range should be construed as being included within the scope of the present invention.

1. A method of manufacturing an ultraviolet light-emitting device, comprising:
a first formation operation of forming a nucleation layer on a growth substrate;
a second formation operation of forming a sacrificial separation layer on the nucleation layer;
a growth operation of growing a light-emitting layer on the sacrificial separation layer;
a bonding operation of bonding the light-emitting layer to a support substrate;
a first removal operation of removing the growth substrate, the nucleation layer, and the sacrificial separation layer; and
a fabrication (FAB) operation of forming a light-emitting device structure by performing a FAB process on the light-emitting layer.

2. The method of claim 1, wherein the nucleation layer includes a low-temperature growth layer and a high-temperature growth layer, which is formed on the low-temperature growth layer and grown at a higher temperature than the low-temperature growth layer, and
a plurality of air voids are formed within the high-temperature growth layer.

3. The method of claim 1, wherein the sacrificial separation layer is formed as a multilayer thin film with a superlattice structure.

4. The method of claim 3, wherein the sacrificial separation layer includes at least one superlattice unit layer,
wherein the superlattice unit layer includes at least one of an AlN layer, an AlₓGa₁₋ₓN layer, or an Al_{y}Ga_{1-y}N layer,
wherein, in a case where y>x, the AlₓGa₁₋ₓN layer satisfies x≤0.48, and
in a case where x>y, the Al_{y}Ga_{1-y}N layer satisfies y≤0.48.

5. The method of claim 1, wherein the light-emitting layer includes an n-type semiconductor layer, an active layer, an electron blocking layer, and a p-type semiconductor layer.

6. The method of claim 1, wherein a seed layer and a polycrystalline diamond (PCD) layer are sequentially stacked on the support substrate, and
in the bonding operation, the light-emitting layer is bonded to the PCD layer.

7. The method of claim 6, further comprising a second removal operation of removing the support substrate and the seed layer after the FAB operation.

8. The method of claim 1, wherein, in the FAB operation, the FAB process is performed such that a width of each of divided portions of the light-emitting layer is formed to be less than or equal to a current spreading length.

9. The method of claim 1, wherein, in the FAB operation, the FAB process is performed such that an n-type ohmic contact electrode surrounds a periphery of each of divided portions of the light-emitting layer.
